(19) United States
(12) Patent Application Publication
(10) Pub. No.: US 2026/0371906 A1
(43) Pub. Date: Nov. 19, 2026

(54) DISPLAY DEVICE

(71) Applicant: LG Display Co., Ltd., Seoul (KR)

(72) Inventors: Sunggon HONG, Paju-si (KR); Minsuk KONG, Paju-si (KR)

(73) Assignee: LG Display Co., Ltd., Seoul (KR)

(21) Appl. No.: 19/638,024

(22) Filed: Apr. 2, 2026

(30) Foreign Application Priority Data
May 15, 2025 (KR) 10-2025-0062939

(51) Int. Cl. H10K 59/80; H10K 59/122; H10K 59/124; H10K 59/38; H10K 59/40; H10K 102/00

(52) U.S. Cl. CPC H10K 59/879; H10K 59/122; H10K 59/38; H10K 59/40; H10K 59/8792; H10K 59/124; H10K 2102/311

(57) ABSTRACT

A display device includes a substrate in which a plurality of sub-pixels each including a light-emitting area and a non-light-emitting area are defined, a first insulating layer disposed on the substrate and having a first refractive index, a second insulating layer disposed on the first insulating layer and having a second refractive index smaller than the first refractive index, and a black matrix disposed on the second insulating layer in the non-light-emitting area, wherein, in the light-emitting area, the second insulating layer has a recess in an upper surface of the second insulating layer.

### CROSS REFERENCE TO RELATED APPLICATION

The present application claims priority to Korean Patent Application No. 10-2025-0062939, filed May 15, 2025, the entire contents of which are incorporated herein for all purposes by this reference.

### BACKGROUND

### Field of the Disclosure

The present specification relates to a display device.

### Description of the Related Art

As the information society develops, various demands for display devices for displaying images are increasing, and various types of display devices, such as liquid crystal display (LCD) devices, organic light-emitting diode (OLED) display devices, etc., are utilized.

A display device includes a plurality of pixels and a plurality of switching elements for driving and controlling the pixels.

### SUMMARY

Various embodiments of the present specification are directed, for example, to providing a display device capable of preventing or reducing external light reflection (or surface reflection).

Various embodiments of the present specification are also directed to providing a display device capable of guiding light incident on a second upper insulating layer among external light to a black matrix.

Various embodiments of the present specification are also directed to providing a display device capable of guiding light reflected by a lower portion of a light-emitting part among external light to a black matrix.

Various embodiments of the present specification are also directed to providing a display device with low reflection and low power consumption.

Various embodiments of the present specification are also directed to providing a display device with improved flexibility which may be applied to foldable products in which a display area is folded.

Objects of the present specification are not limited to the above objects, and other technical objects may be inferred from the following general description and description of example embodiments.

To achieve these objects and other advantages of the present disclosure, as embodied and broadly described herein, a display device according to one or more example embodiments includes a substrate in which a plurality of sub-pixels each including a light-emitting area and a non-light-emitting area are defined, a first insulating layer disposed on the substrate and having a first refractive index, a second insulating layer disposed on the first insulating layer and having a second refractive index smaller than the first refractive index, and a black matrix disposed on the second insulating layer in the non-light-emitting area, wherein, in the light-emitting area, the second insulating layer has a recess in an upper surface of the second insulating layer.

Details of the above and other example embodiments are included in the detailed description and accompanying drawings.

### BRIEF DESCRIPTION OF THE DRAWINGS

The accompanying drawings, which are included to provide a further understanding of the present disclosure and are incorporated in and constitute a part of this application, illustrate various example embodiments of the present disclosure and together with the description serve to explain various principles of the disclosure.

FIG. 1 is a plan view of a display device according to one or more example embodiments.

FIG. 2 is a cross-sectional view illustrating a bent state of the example display panel according to FIG. 1.

FIG. 3 is a cross-sectional view of the display panel according to an example embodiment.

FIG. 4 is a cross-sectional view of a display panel according to another example embodiment.

FIG. 5 is a cross-sectional view of a display panel according to still another example embodiment.

FIG. 6 is a plan view of the display panel according to an example embodiment.

FIG. 7 is a cross-sectional view of a display panel according to yet another example embodiment.

FIG. 8 is an enlarged cross-sectional view of an example thin-film transistor layer in FIG. 7.

FIG. 9 is a cross-sectional view of an example touch part according to FIG. 7.

FIG. 10 is a cross-sectional view of a display panel according to yet another example embodiment.

### DETAILED DESCRIPTION

Hereinafter, various example embodiments will be described with reference to the accompanying drawings.

The same reference numerals indicate the same components unless otherwise specified. In addition, in the drawings, thicknesses, proportions, and dimensions of components may be exaggerated for effective description of technical contents. Scales of components illustrated in the drawings may differ from the actual scale for convenience of description, and thus embodiments of present disclosure are not limited to the scales illustrated in the drawings.

In the specification, where a certain component (or an area, a layer, a portion, etc.) is described as “on,” “connected,” or “coupled to” another component, it means that the certain component may be directly connected/coupled to the other component or still another component may be disposed therebetween.

The term “and/or” includes all one or more combinations that may be defined by the associated configurations.

Terms such as “first,” “second,” and the like may be used to describe various components, but the components are not limited by these terms. The terms are used only for the purpose of referring to one component separately from another. For example, a first component may be referred to as a second component, and similarly, the second component may also be referred to as the first component without departing from the scopes of various embodiments. The singular includes the plural, and vice versa, unless the context clearly dictates otherwise.

Terms such as “under,” “at a lower side,” “above,” and “at an upper side” may be used to describe the positional relationship between the components illustrated in the drawings. The terms are relative concepts and are described with respect to directions marked in the drawings. For example, as long as a more specific term like “immediately” or “directly” is not used, one or more other portions may be positioned between two portions. The spatially relative terms like “below or beneath,” “lower,” “above,” “upper,” etc., can be used to conveniently describe the correlation between one element or components and another element or components as shown in the drawings. The spatially relative terms should be understood as the terms including different directions of elements in use or operation in addition to the directions shown in the drawings. For example, in case of turning the element shown in the drawing upside down, an element described as being disposed “below” or “beneath” another element may be disposed “above” the other element. Accordingly, the example term “below” may include both downward and upward directions.

It should be understood that terms such as “includes” or “has” are intended to specify the presence of features, numbers, steps, operations, components, parts, or a combination thereof described in the specification and do not preclude the presence or addition possibility of one or more other features, numbers, steps, operations, components, parts, or combinations thereof in advance.

Features of various embodiments of the present specification may be coupled or combined partially or entirely, various technological interworking and driving are made possible, and various embodiments may be implemented independently of each other or implemented together in an associated relationship.

Hereinafter, a display device according to various example embodiments of the present specification will be described with reference to the accompanying drawings.

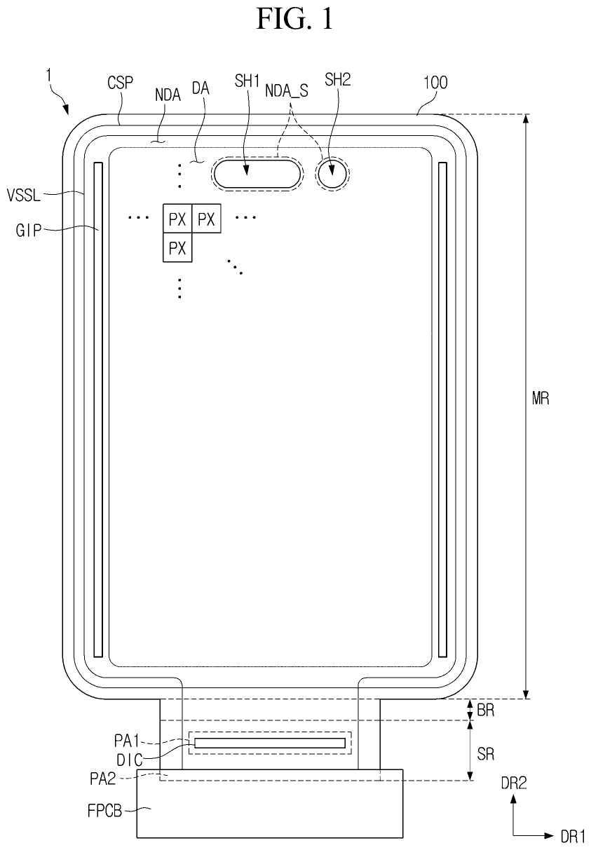

FIG. 1 is a plan view of a display device according to one or more example embodiments.

As shown in FIG. 1, a display device 1 according to one or more example embodiments may include a display panel 100. The display panel 100 may include a display area DA including a plurality of pixels PX and a non-display area NDA around the display area DA. The flat surface shape of the display area DA may have a rectangular shape. However, various embodiments of the present specification are not limited thereto, and the flat surface shape of the display area DA may be a square, circular, elliptical, or other polygonal shapes. For example, the display area DA may have a rectangular shape with rounded corners, but is not limited thereto, and may also have a rectangular shape with angled corners.

In various embodiments, a first direction DR1 and a second direction DR2 are different directions and intersect each other, for example, directions that intersect vertically in a plan view. In FIG. 1, the first direction DR1 may be generally the same as an extension direction of short edges of the display panel 100, and the second direction DR2 may be the same as an extension direction of long edges of the display panel 100. However, the directions described in various embodiments should be understood as indicating relative directions, and various embodiments are not limited to the described directions.

The display area DA may include short edges extending in the first direction DR1 and long edges extending in the second direction DR2. The non-display area NDA may surround the display area DA. The non-display area NDA may be disposed at one side and the other side of the display area DA in the first direction DR1 and one side and the other side of the display area DA in the second direction DR2.

The display panel 100 may further include a sensor non-display area NDA_S and a sensor hole SH surrounded by the sensor non-display area NDA_S. The sensor holes SH1 and SH2 may be surrounded by the display area DA in a plan view. The sensor holes SH1 and SH2 may be, for example, two sensor holes as in FIG. 1, but various embodiments of the present specification are not limited thereto. For example, the sensor hole may be provided as one sensor hole. The two sensor holes SH1 and SH2 may each include a sensor hole in which an infrared sensor is disposed and a sensor hole in which a camera sensor is disposed, but various embodiments of the present specification are not limited thereto. The sensor non-display area NDA_S may be disposed between the sensor holes SH1 and SH2 and the display area DA. The sensor non-display area NDA_S may completely surround the sensor holes SH1 and SH2. A pixel PX may not be disposed in the sensor non-display area NDA_S.

In some embodiments, the sensor holes SH1 and SH2 are not disposed, and an infrared sensor or a camera sensor may be disposed in the display area DA. In this case, the number of pixels PX per area of the display area DA in which the infrared sensor or the camera sensor is disposed may be less than the number of pixels PX per area of the display area DA in which the infrared sensor or the camera sensor is not disposed. That is, the display area DA in which the infrared sensor or the camera sensor is disposed may further include a transmissive area.

A gate driving unit GIP may be disposed in the non-display area NDA positioned at the one side and the other side of the display area DA in the first direction DR1. A low-potential voltage line VSSL may be disposed outside the gate driving unit GIP in the non-display area NDA. For example, as illustrated in FIG. 1, the low-potential voltage line VSSL may extend from a printed circuit board FPCB, pass a sub-region SR and a bending region BR, may be positioned outside the gate driving unit GIP on the non-display area NDA, and disposed to surround the display area DA.

The non-display area NDA positioned at the other side of the display area DA in the second direction DR2 may further extend outward from a central portion of the other side toward the other side of the display area DA in the second direction DR2. A width of the non-display area NDA in the first direction DR1 further extending outward from the central portion of the other side toward the other side of the display area DA in the second direction DR2 may be smaller than a width of the non-display area NDA in the first direction DR1 adjacent to the other side of the display area DA in the second direction DR2.

The display device 1 may include a main region MR, the sub-region SR, and the bending region BR between the main region MR and the sub-region SR. The display area DA and the non-display area NDA surrounding four surfaces of the display area DA may form the main region MR, and a portion further extending outward from the central portion of the other side toward the other side of the display area DA in the second direction DR2 may form the bending region BR and the sub-region SR. The bending region BR may be disposed between the sub-region SR and the main region MR. The sub-region SR may include a first pad area PA1 and a second pad area PA2 positioned at an end portion of the other side of the sub-region SR in the second direction DR2. The display device 1 may further include a data driving unit DIC and a printed circuit board FPCB. The data driving unit DIC may be disposed in the first pad area PA1, and the printed circuit board FPCB may be attached to the second pad area PA2. A plurality of pads connected to the data driver 300 and the printed circuit board 500 may be disposed in each of the first pad area PA1 and the second pad area PA2. A plurality of pads connected to the data driving unit DIC and the printed circuit board FPCB may be disposed in each of the first pad area PA1 and the second pad area PA2. The data driving unit DIC may be configured, for example, in the form of a driving chip (IC), but is not limited thereto. In an example embodiment, a case in which the data driving unit DIC is disposed by a chip on plastic method in which the data driving unit DIC is directly mounted on the display panel 100 is described, but various embodiments of the present specification are not limited thereto, and the data driving unit DIC may be disposed by a chip on glass or chip on film method.

The display panel 100 according to an example embodiment may further include a crack sensing pattern CSP surrounding the low-potential voltage line VSSL. The crack sensing pattern CSP may be disposed to completely surround the display area DA as illustrated in FIG. 1. For example, the crack sensing pattern CSP may be disposed outside the low-potential voltage line VSSL. However, various embodiments of the present specification are not limited thereto, and a part of the crack sensing pattern CSP may not be disposed in the non-display area NDA of the other side of the display area DA in the second direction DR2.

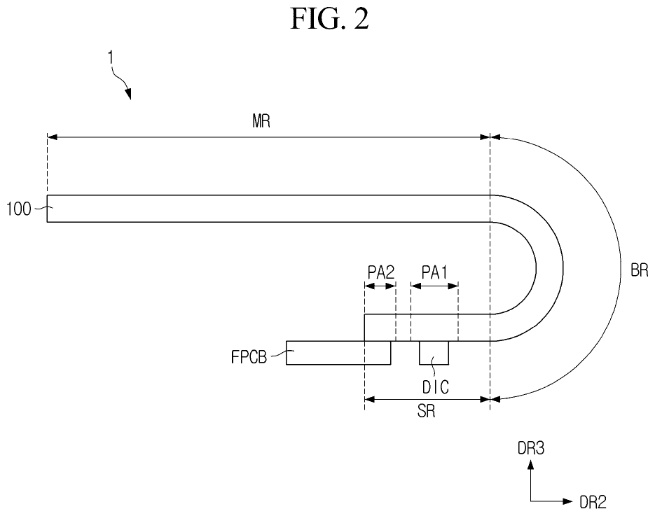

FIG. 2 is a cross-sectional view illustrating a bent state of the example display panel according to FIG. 1.

As shown in FIG. 2, the bending region BR of the display panel 100 of the display device 1 according to one or more example embodiments may be bent in a thickness direction (or a third direction DR3). Accordingly, the main region MR and the sub-region SR may overlap each other in the thickness direction. The display panel 100 may be bent such that a lower surface of the main region MR faces an upper surface of the sub-region SR. The printed circuit board FPCB may be attached to an end portion of the sub-region SR.

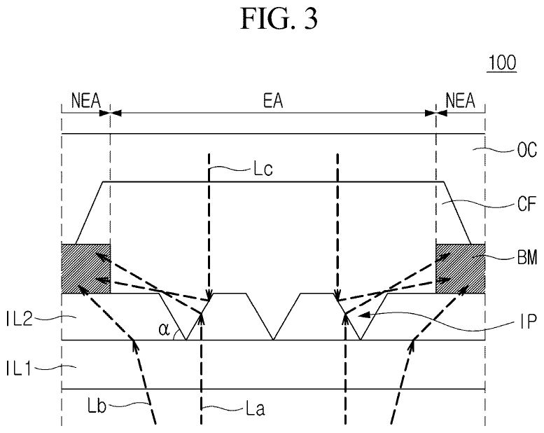

FIG. 3 is a cross-sectional view of the display panel according to an example embodiment.

As shown in FIG. 3, a display panel 100 according to an example embodiment may include insulating layers IL1 and IL2, a black matrix BM on the insulating layers IL1 and IL2, a color filter CF on the black matrix BM, and a planarization layer OC on the color filter CF. Although not illustrated, the display panel 100 may include a substrate. A light-emitting area EA and a non-light-emitting area NEA may be defined in the substrate.

The substrate may include one or more plastic materials or glass. For example, the substrate may be a multi-layer substrate containing multiple plastic materials, such as polyimide, but is not limited thereto. For example, the substrate may include a first substrate portion and a second substrate portion that contain an organic material, and a third substrate portion including an inorganic material, but various embodiments of the present specification are not limited thereto.

The insulating layers IL1 and IL2 may include a first insulating layer IL1 (or a first upper insulating layer) and a second insulating layer IL2 (or a second upper insulating layer) on the first insulating layer IL1. The insulating layers IL1 and IL2 may contain an organic insulation material or an inorganic insulation material. The first insulating layer IL1 may have a first refractive index, and the second insulating layer IL2 may have a second refractive index. The second refractive index may be smaller than the first refractive index. Conversely, the first refractive index may be greater than the second refractive index. FIG. 3 illustrates that the single first insulating layer IL1 and the single second insulating layer IL2, two or more first insulating layers IL1 and two or more second insulating layers IL2 may be alternately stacked. In some embodiments, the first and second refractive indices may be determined during the manufacturing process of the first and second insulating layers IL1 and IL2. For example, the first and second insulating layers IL1 and IL2 may contain the same material and may be manufactured in such a way that more bubbles are formed within the second insulating layer IL2 than within the first insulating layer IL1. In this case, a density of the first insulating layer IL1 may be greater than that of the second insulating layer IL2.

In the light-emitting area EA, the second insulating layer IL2 may have a recess IP disposed in an upper surface thereof. The recess IP may be disposed in the upper surface of the second insulating layer IL2 and may completely pass through the second insulating layer IL2 in the thickness direction. A width of the recess IP may increase from the bottom to the top. Conversely, the width of the recess IP may decrease from the top to the bottom. For example, a cross-sectional shape of the recess IP may have a V shape. FIG. 3 illustrates three recesses IP in one light-emitting area EA, the number of recesses IP may be one, two, or four or more.

The black matrix BM may be disposed on the second insulating layer IL2. The black matrix BM may be disposed in the non-light-emitting area NEA. The black matrix BM may include a black-based material. For example, the black matrix BM may include a light-blocking material or a light-absorbing material. For example, the black matrix BM may be formed of a material including a black pigment, a black dye, etc. In some embodiments, the black matrix BM may include a structure in which a red color filter, a green color filter, and a blue color filter are stacked.

The color filter CF may be disposed on the black matrix BM. The color filter CF may block a specific color from light emitted from the light-emitting area of each sub-pixel. For example, the color filter CF may include a red color filter, a green color filter, or a blue color filter. The color filter CF may fill the recess IP. The color filter CF may be in direct contact with side and upper surfaces of the second insulating layer IL2 and may have a refractive index greater than that of the second insulating layer IL2. The recess IP may be provided as a plurality of recesses, and a single color filter CF may overlap the plurality of recesses IP. A thickness of the color filter CF overlapping the recess IP may be greater than a thickness of the color filter CF overlapping the second insulating layer IL2.

The planarization layer OC may further be disposed on the color filter CF. The planarization layer OC may planarize a step caused by the color filter CF. The planarization layer OC may contain an organic material, but various embodiments of the present specification are not limited thereto.

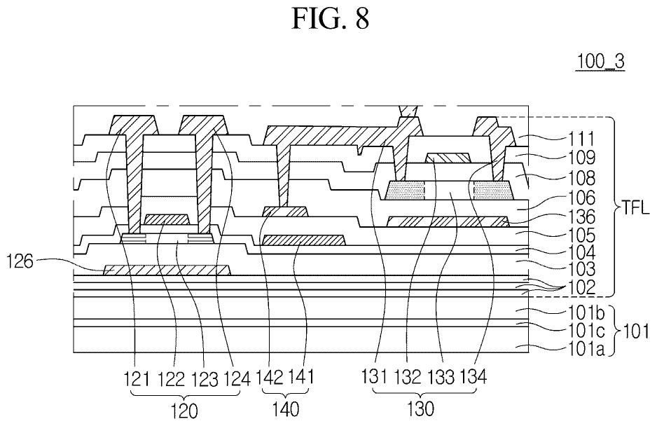

As illustrated in FIG. 3, light La and Lb incident from the outside and reflected by at least one electrode of thin-film transistors (TR) 120 and 130 (see FIG. 8) disposed below the first insulating layer IL1 may propagate to the black matrix BM.

More specifically, the light Lb may be refracted at an interface between the first insulating layer IL1 and the second insulating layer IL2 and may propagate to the black matrix BM. As described above, since the second refractive index of the second insulating layer IL2 is smaller than the first refractive index of the first insulating layer IL1, the light Lb obliquely incident on the first insulating layer IL1 may be refracted at a refractive angle greater than an incident angle at the interface between the first and second insulating layers IL1 and IL2, may propagate to the black matrix BM, and may be absorbed by the black matrix BM, thereby preventing or reducing surface reflection (or external light reflection).

The light La may pass through the first insulating layer IL1, may be refracted at an interface between the second insulating layer IL2 and the color filter CF, and may propagate to the black matrix BM. A refractive index of the color filter CF may be greater than the second refractive index. Since the refractive index of the color filter CF is greater than the second refractive index and the second insulating layer IL2 includes the recess IP, the light La may be refracted at a smaller angle of refraction than the incident angle at the interface between side surfaces of the second insulating layer IL2 in which the recess IP is formed and the color filter CF, may propagate to the black matrix BM, and may be absorbed by the black matrix BM, thereby preventing or reducing surface reflection (or external light reflection).

Meanwhile, externally incident light Lc may pass through the color filter CF, and the light Lc having a wavelength other than a wavelength at which the color filter CF absorbs light may propagate to the interface between the second insulating layer IL2 and the color filter CF. The light Lc may be totally reflected at the interface between the side surface of the second insulating layer IL2 and the color filter CF, may propagate to the black matrix BM, and may be absorbed by the black matrix BM, thereby preventing or reducing surface reflection (or external light reflection). As described above, since the second refractive index of the second insulating layer IL2 is smaller than that of the color filter CF and the second insulating layer IL2 includes the recess IP, the light Lc incident on the interface between the side surface of the second insulating layer IL2 and the color filter CF may be totally reflected.

According to an example embodiment, in the light-emitting area EA, an angle α of the side surface of the second insulating layer IL2 formed by the recess IP may be smaller than or equal to about 20°. For example, when the angle α of the side surface of the second insulating layer IL2 exceeds about 20°, the light Lc directly incident from the outside may not propagate to the black matrix BM but may directly propagate upward from the black matrix BM and propagate outward when totally reflected at the side surface of the second insulating layer IL2.

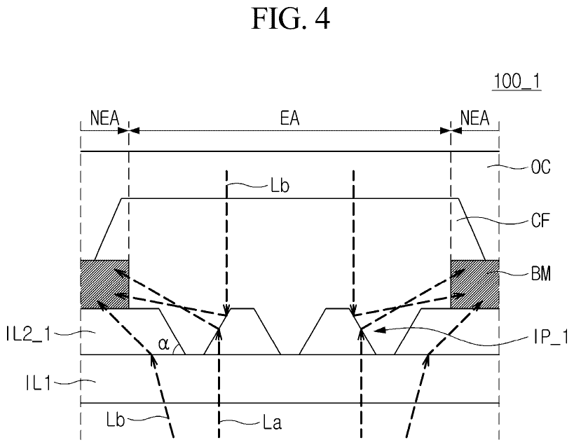

FIG. 4 is a cross-sectional view of a display panel according to another example embodiment.

As shown in FIG. 4, a cross-sectional shape of an recess IP_1 of a display panel 100_1 according to this example embodiment may have an inverted trapezoidal shape, which differs from the display panel 100 according to FIG. 3. Even in the case of the display panel 100_1 according to this example embodiment, the light La and Lb reflected by at least one electrode of the thin-film transistors (TR) 120 and 130 (see FIG. 8) disposed below the first insulating layer IL1 may propagate to the black matrix BM, propagate to the black matrix BM due to the relationship between the refractive indices of the first insulating layer IL1, the second insulating layer IL2_1, and the color filter CF, and the recess IP_1 of the second insulating layer IL2_1, and may be absorbed by the black matrix BM, thereby preventing or reducing surface reflection (or external light reflection).

In addition, the externally incident light Lc may be totally reflected at the interface between a side surface of the second insulating layer IL2_1 and the color filter CF due to the refractive index relationship between the second insulating layer IL2_1 and the color filter CF, and the recess IP_1 of the second insulating layer IL2_1, may propagate to the black matrix BM, and may be absorbed by the black matrix BM, thereby preventing or reducing surface reflection (or external light reflection).

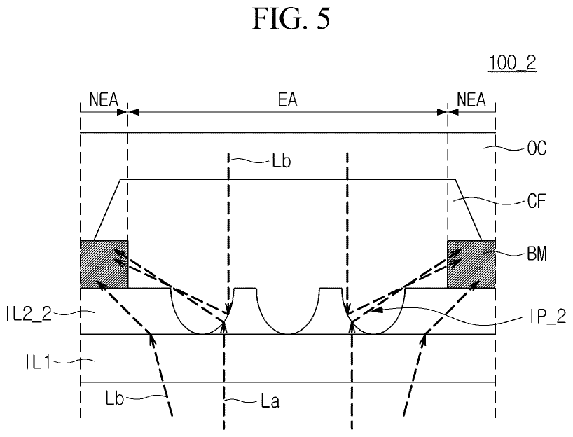

FIG. 5 is a cross-sectional view of a display panel according to still another example embodiment.

As shown in FIG. 5, a cross-sectional shape of a recess IP_2 of a display panel 100_2 according to this example embodiment may have a U shape, which differs from the display panel 100 according to FIG. 3. Even in the case of the display panel 100_2 according to this example embodiment, the light La and Lb reflected by at least one electrode of the thin-film transistors (TR) 120 and 130 (see FIG. 8) disposed below the first insulating layer IL1 may propagate to the black matrix BM, propagate to the black matrix BM due to the relationship between the refractive indices of the first insulating layer IL1, a second insulating layer IL2_2, and the color filter CF, and the recess IP_2 of the second insulating layer IL2_2, and may be absorbed by the black matrix BM, thereby preventing or reducing surface reflection (or external light reflection).

In addition, the externally incident light Lc may be totally reflected at the interface between a side surface of the second insulating layer IL2_2 and the color filter CF due to the refractive index relationship between the second insulating layer IL2_2 and the color filter CF, and the recess IP_2 of the second insulating layer IL2_2, may propagate to the black matrix BM, and may be absorbed by the black matrix BM, thereby preventing or reducing surface reflection (or external light reflection).

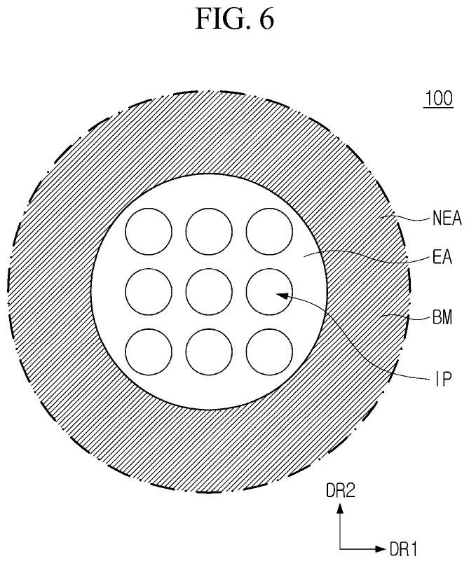

FIG. 6 is a plan view of the display panel according to an example embodiment.

As shown in FIG. 6, in the case of the display panel 100 according to an example embodiment, as described above, a plurality of recesses IP may be disposed in one light-emitting area EA. The recesses IP may not be disposed in the non-light-emitting area NEA. FIG. 6 illustrates that nine recesses IP are disposed in one light-emitting area EA, but various embodiments of the present specification are not limited thereto.

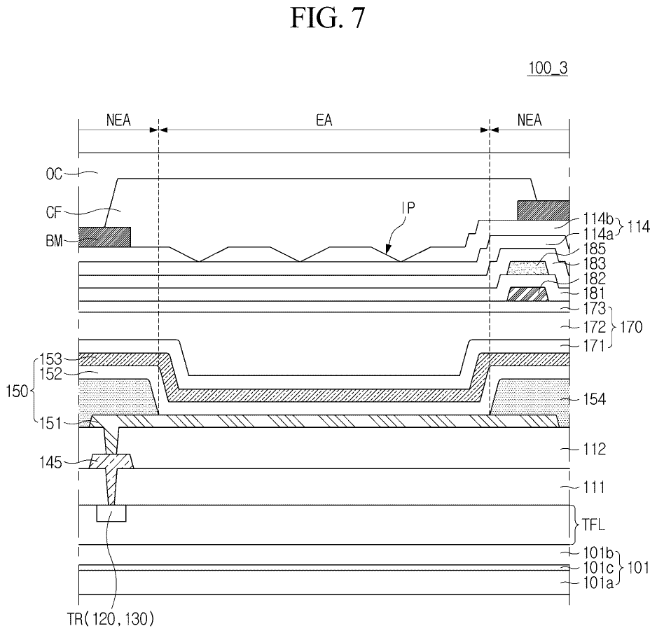

FIG. 7 is a cross-sectional view of a display panel according to yet another example embodiment. FIG. 8 is an enlarged cross-sectional view of an example thin-film transistor layer in FIG. 7.

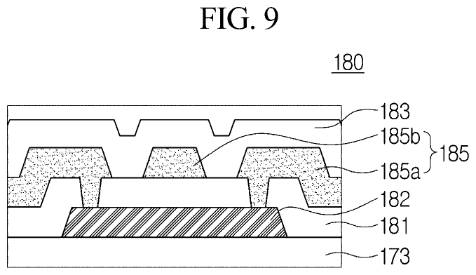

As shown in FIG. 7, a display panel 100_3 according to this example embodiment may include a substrate 101, a thin-film transistor layer TFL on the substrate 101, the first protective layer 111 on the thin-film transistor layer TFL, a second protective layer 112 on the first protective layer 111, a light-emitting part 150, an encapsulation part 170, a touch part 180 (see FIG. 9), a filter insulating layer 114, the black matrix BM, the color filter CF, and the planarization layer OC.

In one embodiment, the substrate 101 may include a first layer 101a, a second layer 101c on the first layer 101a, and a third layer 101b on the second layer 101c, but is not limited thereto.

As shown in FIG. 8, the thin-film transistor layer TFL may include at least one thin-film transistor (TR) 120 and 130 and at least one insulating layer.

As shown in FIG. 8, the thin-film transistor layer TFL may include a buffer layer 102, a first thin-film transistor 120, a second thin-film transistor 130, a storage electrode 140, and insulating layers 103, 104, 105, 106, 108, and 109.

The buffer layer 102 may be disposed on the substrate 101. The buffer layer 102 can minimize or delay the diffusion of moisture or oxygen penetrating the substrate 101. The buffer layer 102 may be formed by alternately stacking silicon nitride (SiNₓ) and silicon oxide (SiOₓ) at least once, but is not limited thereto.

A first light-shielding layer 126 may be disposed on the buffer layer 102. The first light-shielding layer 126 can prevent or suppress light from transmitting a first semiconductor layer 123 of the first thin-film transistor 120. For example, the first semiconductor layer 123 may be disposed to overlap the first light-shielding layer 126.

A first insulating layer 103 may be disposed on the first light-shielding layer 126. The first insulating layer 103 may be formed of the same material as the buffer layer 102, but is not limited thereto.

The first thin-film transistor 120 may be disposed on the first insulating layer 103. The first thin-film transistor 120 may include a first input electrode 121, a first gate electrode 122, a first semiconductor layer 123, and a first output electrode 124.

The first semiconductor layer 123 may be disposed on the first insulating layer 103. The first semiconductor layer 123 may include a metal oxide semiconductor, such as indium-gallium-zinc oxide (IGZO), and a silicon-based semiconductor material, such as amorphous silicon, polycrystalline silicon, etc., but is not limited thereto. The first semiconductor layer 123 may include a channel region, a source region, and a drain region.

A second insulating layer 104 may be disposed on the first semiconductor layer 123. The second insulating layer 104 may be formed of the same material as the first insulating layer 103, but is not limited thereto.

The first gate electrode 122 may be disposed on the second insulating layer 104. The first gate electrode 122 may be disposed on the second insulating layer 104 to overlap the channel region of the first semiconductor layer 123. The first gate electrode 122 may be formed of a single layer or multiple layers formed of molybdenum (Mo), copper (Cu), titanium (Ti), aluminum (Al), chromium (Cr), gold (Au), nickel (Ni), neodymium (Nd), or compounds thereof. The first gate electrode 122 may be disposed together with a gate line.

A third insulating layer 105 may be disposed on the first gate electrode 122. The third insulating layer 105 may be formed of the same material as the first insulating layer 103 or the second insulating layer 104.

The first input electrode 121 and the first output electrode 124 may be disposed on the third insulating layer 105.

The first input electrode 121 and the first output electrode 124 may be electrically connected to the first semiconductor layer 123 via contact holes. The first input electrode 121 and the first output electrode 124 may be formed of a metal material.

The first input electrode 121 and the first output electrode 124 may be disposed together with the data line.

The storage electrode 140 may be disposed to be spaced apart from the first thin-film transistor 120. The storage electrode 140 may include a first storage electrode 141 and a second storage electrode 142.

The first storage electrode 141 may be disposed on the same layer as the first gate electrode 122 and may be made of the same material as the first gate electrode 122, but is not limited thereto.

The second storage electrode 142 may be disposed on the first storage electrode 141. The second storage electrode 142 may be disposed on the third insulating layer 105, and the third insulating layer 105 between the first storage electrode 141 and the second storage electrode 142 may be used as a dielectric to generate a capacitance.

The second thin-film transistor 130 may be disposed to be spaced apart from the first thin-film transistor 120 and the storage electrode 140. The second thin-film transistor 130 may include a second input electrode 131, a second gate electrode 132, a second semiconductor layer 133, and a second output electrode 134.

A second light-shielding layer 136 may be disposed on the same layer as the second storage electrode 142.

For example, the second semiconductor layer 133 may be disposed to overlap the second light-shielding layer 136.

A fourth insulating layer 106 may be disposed on the second light-shielding layer 136. The fourth insulating layer 106 may be made of the same material as the first insulating layer 103, the second insulating layer 104, or the third insulating layer 105, but is not limited thereto.

The second semiconductor layer 133 may be disposed on the fourth insulating layer 106. The second semiconductor layer 133 may include a source area, a drain area, and a channel area between the source area and the drain area.

The second semiconductor layer 133 may include a metal oxide semiconductor, such as IGZO or the like, and a silicon-based semiconductor material, such as amorphous silicon, polycrystalline silicon, etc., but is not limited thereto.

A fifth insulating layer 108 may be disposed on the second semiconductor layer 133. The fifth insulating layer 108 may be made of the same material as the first insulating layer 103, the second insulating layer 104, the third insulating layer 105, or the fourth insulating layer 106, but is not limited thereto.

The second gate electrode 132 may be disposed on the fifth insulating layer 108.

The second gate electrode 132 may be made of the same material as the first gate electrode 122.

A sixth insulating layer 109 may be disposed on the second gate electrode 132. The sixth insulating layer 109 may be made of the same material as the first insulating layer 103, the second insulating layer 104, the third insulating layer 105, the fourth insulating layer 106, or the fifth insulating layer 108, but is not limited thereto.

The first input electrode 121, the first output electrode 124, the third storage electrode 143, the second input electrode 131, and the second output electrode 134 may be disposed on the sixth insulating layer 109.

The second input electrode 131 and the second output electrode 134 may be formed of the same material as the first input electrode 121 and the first output electrode 124 and disposed on the same layer.

The first thin-film transistor 120 may be a switching transistor, and the second thin-film transistor 130 may be a driving transistor, but various embodiments of the present specification are not limited thereto.

The first protective layer 111 may be disposed on the first input electrode 121 and the first output electrode 124.

Referring back to FIG. 7, the first protective layer 111 may be disposed on the thin-film transistor layer TFL.

The first protective layer 111 may planarize an upper portion of the first thin-film transistor 120 and protect the first thin-film transistor 120. The first protective layer 111 may be made of an organic material.

A second protective layer 112 may be disposed on the first protective layer 111. The second protective layer 112 may be formed of the same material as the first protective layer 111, but is not limited thereto.

A connection electrode 145 may be disposed between the first protective layer 111 and the second protective layer 112.

The connection electrode 145 may electrically connect the thin-film transistor TR to the light-emitting part 150.

The light-emitting part 150 may be disposed on the second protective layer 112. The light-emitting part 150 may include the first electrode 151, the organic layer 152, and the second electrode 153.

The first electrode 151 may be disposed on the second protective layer 112. The first electrode 151 may be electrically connected to the thin-film transistor TR via a contact hole formed in the second protective layer 112. The first electrode 151 may be an anode electrode, but various embodiments of the present specification are not limited thereto. The first electrode 151 may be a reflective electrode that reflects light, but is not limited thereto. The first electrode 151 may include a metal material with high reflectivity, such as a stacked structure (Ti/Al/Ti) of aluminum (Al) and titanium (Ti), a stacked structure (ITO/Al/ITO) of aluminum (Al) and indium tin oxide (ITO), or an APC alloy, and may be formed of a single layer or multiple layers, but is not limited thereto.

The organic layer 152 may be disposed on the first electrode 151.

The second electrode 153 may be disposed on the organic layer 152.

The bank 154 may be disposed to expose the first electrode 151. The bank 154 may define openings (or light-emitting areas EA1, EA2, and EA3) of the sub-pixels and may be disposed to cover an edge portion (or a periphery) of the first electrode 151. That is, non-light-emitting areas NEA may correspond to boundaries between adjacent sub-pixels.

The bank 154 may include a black-based material. For example, the bank 154 may be formed of a material containing black pigment, or an organic material, such as a benzocyclobutene resin, a polyimide resin, an acrylic resin, a photosensitive polymer, etc., but various embodiments of the present specification are not limited thereto. When the bank 154 is formed of a material containing black pigment, black dye, etc., the bank 154 may be a black bank. When the bank 154 is formed of a material containing black pigment or black dye, it is possible to block external light or light reflected from the outside, thereby preventing or reducing surface reflection due to the external light. Although not illustrated, a spacer may be further disposed on the bank 154.

The encapsulation part 170 may be disposed on the bank 154 or the light-emitting part 150. The encapsulation part 170 may include one or more insulating layers. For example, the encapsulation part 170 may include the first encapsulation layer 171, the second encapsulation layer 172 disposed on the first encapsulation layer 171, and the third encapsulation layer 173 on the second encapsulation layer 172. The encapsulation part 170 may include one or more inorganic layers and one or more organic layers. For example, the first encapsulation layer 171 and the third encapsulation layer 173 may include an inorganic material, and the second encapsulation layer 172 may include an organic material.

FIG. 9 is a cross-sectional view of an example touch part according to FIG. 7.

As shown in FIGS. 7 and 9, the touch part 180 may be disposed on the encapsulation part 170.

The touch part 180 may include a first touch conductive layer, a touch buffer layer 181, a second touch conductive layer, and a touch insulating layer 183. A first touch conductive layer may be disposed on the third encapsulation layer 173. The first touch conductive layer may include a bridge electrode 182. The touch buffer layer 181 may be disposed on the first touch conductive layer. The touch buffer layer 181 can prevent or suppress a short circuit between touch electrodes. For example, the touch buffer layer 181 may contain an organic or inorganic material. The second touch conductive layer may be disposed on the touch buffer layer 181. The second touch conductive layer may include a sensor electrode 185. The touch insulating layer 183 may be disposed on the second touch conductive layer. The touch insulating layer 183 may include an organic material or an inorganic material. The bridge electrode 182 and the sensor electrode 185 may be disposed in the non-light-emitting area NEA, but various embodiments of the present specification are not limited thereto.

The bridge electrode 182 and the sensor electrode 185 may be disposed at the boundaries between adjacent sub-pixels. For example, the bridge electrode 182 and the sensor electrode 185 may be disposed in the non-light-emitting areas NEA. The bridge electrode 182 and the sensor electrode 185 may overlap the black matrix BM to be described below in the thickness direction. The black matrix BM may cover the bridge electrode 182 and the sensor electrode 185. Accordingly, the bridge electrode 182 and the sensor electrode 185 can be prevented or blocked from being visible from the outside.

The second touch conductive layer may include a first sensor electrode 185a and a second sensor electrode 185b. The sensor electrode 185 may include the first sensor electrode 185a extending in the first direction DR1 (see FIG. 1) and the second sensor electrode 185b extending in the second direction DR2 (see FIG. 1) different from the first direction DR1.

Although not illustrated, the bridge electrode 182 may be electrically connected to the first sensor electrode 185a via a contact hole formed in the touch buffer layer 181. For example, the first sensor electrode 185a and the bridge electrode 182 may extend in the first direction DR1 (see FIG. 1).

The sensor electrode 185 and the bridge electrode 182 may include a metal material. For example, the sensor electrode 185 and the bridge electrode 182 may be made of titanium (Ti), nickel (Ni), aluminum (Al), or an alloy thereof and formed of a triple layer, such as titanium (Ti)/aluminum (Al)/titanium (Ti), but various embodiments of the present specification are not limited thereto.

Referring back to FIG. 7, the filter insulating layer 114 may be disposed on the touch insulating layer 183. The filter insulating layer 114 may be formed of an inorganic insulation material, such as silicon nitride (SiNₓ) or silicon oxide (SiOₓ), but various embodiments of the present specification are not limited thereto, and the filter insulating layer 114 may be formed of an organic insulation material.

The filter insulating layer 114 in FIG. 7 may be the same as the insulating layers IL1 and IL2 in FIG. 3. That is, a first layer 114a of the filter insulating layer 114 may be the same as the first insulating layer IL1 in FIG. 3, and a second layer 114b may be the same as the second insulating layer IL2 in FIG. 3. The second layer 114b may have the recess IP. Since the first and second layers 114a and 114b of the filter insulating layer 114 are the same as the first and second insulating layers IL1 and IL2 in FIG. 3, the detailed descriptions thereof will be omitted.

The black matrix BM may be disposed on the filter insulating layer 114. The black matrix BM may include a black-based material. For example, the black matrix BM may include a light-blocking material or a light-absorbing material. For example, the black matrix BM may be formed of a material including a black pigment, a black dye, etc. For example, a width of the black matrix BM may be smaller than a width of the bank 154.

For example, separation distances between an end(a side surface) of the black matrix BM and boundaries between the light-emitting areas EA and the non-light-emitting area NEA may be longer than separation distances between an end(a side surface) of the bank 154 and the boundaries between the light-emitting areas EA and the non-light-emitting area NEA. The end of the bank 154 may be aligned with the boundaries between the light-emitting areas EA and the non-light-emitting area NEA, but various embodiments of the present specification are not limited thereto. In the case of the display panel 100 according to an example embodiment, since the bank 154 may contain a black-based material and the separation distances between the end of the black matrix BM and the boundaries between the light-emitting areas EA and the non-light-emitting area NEA may be longer than the separation distances between the end of the bank 154 and the boundaries between the light-emitting areas EA and the non-light-emitting area NEA, light may be emitted upward with wider viewing angles as much as the separation distances between the end of the black matrix BM and the boundaries between the light-emitting areas EA and the non-light-emitting area NEA. Accordingly, it is possible to prevent or suppress a reduction in luminance due to the viewing angle. However, when the separation distances between the end of the black matrix BM and the boundaries between the light-emitting areas EA and the non-light-emitting area NEA are longer than the separation distances between the end of the bank 154 and the boundaries between the light-emitting areas EA and the non-light-emitting area NEA and the bank 154 is formed of only a transparent material, externally incident light may be reflected by the bank 154, resulting in visible ring-shaped artifacts. However, in the display panel 100 according to an example embodiment, the externally incident light may be absorbed or blocked by the bank 154 including a black-based material, thereby preventing or suppressing the occurrence of the ring-shaped artifacts.

The color filter CF may be disposed on the black matrix BM.

For example, each of the color filters CF may be in direct contact with side and upper surfaces of the black matrix BM.

The planarization layer OC may be disposed on the color filter CF.

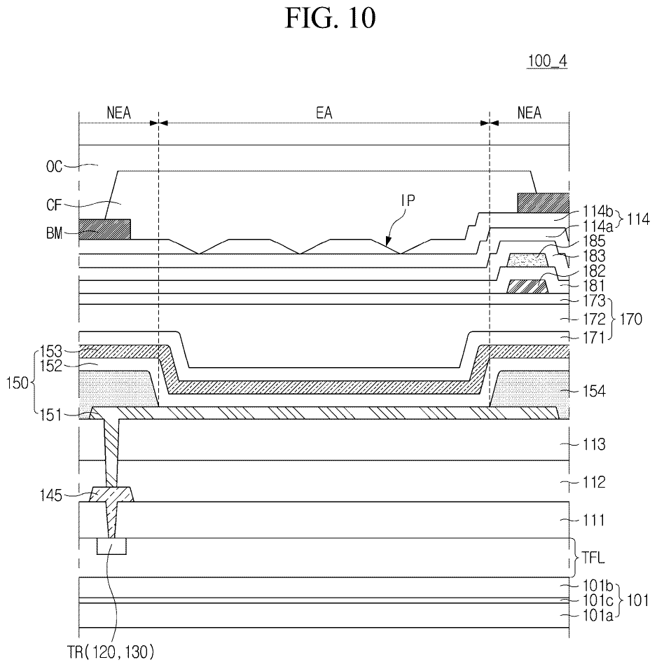

FIG. 10 is a cross-sectional view of a display panel according to yet another example embodiment.

As shown in FIG. 10, a display panel 100_4 according to this example embodiment differs from the example display panel 100_3 according to FIG. 9 in that it further includes the third protective layer 113.

The third protective layer 113 may be disposed between the second protective layer 112 and the first electrode 151, and the first electrode 151 may be electrically connected to the connection electrode 145 through the third protective layer 113 and the second protective layer 112.

Since the remaining parts have been described above with reference to FIG. 9, the detailed descriptions thereof will be omitted.

A display device according to various embodiments of the present specification may be described as follows.

According to various example embodiments of the present specification, a display device may include a substrate in which a plurality of sub-pixels each including a light-emitting area and a non-light-emitting area are defined, a first insulating layer disposed on the substrate and having a first refractive index, a second insulating layer disposed on the first insulating layer and having a second refractive index smaller than the first refractive index, and a black matrix disposed on the second insulating layer in the non-light-emitting area, in which, in the light-emitting area, the second insulating layer has a recess in an upper surface of the second insulating layer.

In the display device according to various example embodiments of the present specification, an angle of a side surface of the second insulating layer may be 20° or less.

In the display device according to various example embodiments of the present specification, a width of the recess may increase upward.

In the display device according to various example embodiments of the present specification, a cross-sectional shape of the recess may have a V shape, an inverted trapezoidal shape, or a U shape.

The display device according to various example embodiments of the present specification may further include a color filter on the black matrix and the second insulating layer, in which the color filter may fill the recess.

In the display device according to various example embodiments of the present specification, the color filter may be in direct contact with the side surfaces and the upper surface of the second insulating layer.

In the display device according to various example embodiments of the present specification, a refractive index of the color filter may be greater than a refractive index of the second insulating layer.

In the display device according to various example embodiments of the present specification, in the light-emitting area, the recess may be provided as a plurality of recesses, and the plurality of recesses may overlap a single color filter.

In the display device according to various example embodiments of the present specification, a thickness of a portion of the color filter overlapping the recess may be greater than a thickness of a portion of the color filter overlapping the second insulating layer.

The display device according to various example embodiments of the present specification may further include a thin-film transistor layer between the substrate and the first insulating layer, a light-emitting part between the thin-film transistor layer and the first insulating layer, and a touch part between the light-emitting part and the first insulating layer, in which the first insulating layer may be in direct contact with the touch part.

In the display device according to various example embodiments of the present specification, the touch part may include a first touch conductive layer, a touch buffer layer on the first touch conductive layer, a second touch conductive layer on the touch buffer layer, and a touch insulating layer on the second touch conductive layer, and the first insulating layer may be in direct contact with the touch insulating layer.

In the display device according to various example embodiments of the present specification, the light-emitting part may include a first electrode, an organic layer on the first electrode, and a second electrode on the organic layer, and the display device may further include a bank which covers a periphery of the first electrode and has a black-based material.

In the display device according to various example embodiments of the present specification, a distance between a side surface of the bank and the light-emitting area may be shorter than a distance between a side surface of the black matrix and the light-emitting area.

In the display device according to various example embodiments of the present specification, each of the first insulating layer and the second insulating layer may include an inorganic insulation material.

According to various example embodiments of the present specification, since the second upper insulating layer having the recess has a lower refractive index than the first upper insulating layer disposed thereunder and the color filter having a high refractive index is disposed on the second upper insulating layer, external light reflection (or surface reflection) can be prevented or reduced by guiding external light incident on the second upper insulating layer to the black matrix

According to various example embodiments of the present specification, since the second upper insulating layer having the recess has a lower refractive index than the first upper insulating layer disposed thereunder and the color filter having a high refractive index is disposed on the second upper insulating layer, external light reflection (or surface reflection) can be prevented or reduced by guiding the light reflected by the lower portion of the light-emitting part among external light to the black matrix.

According to various example embodiments of the present specification, since the angle of the side surface of the second upper insulating layer in which the recess is disposed is 20° or less, the incident external light can be guided to the black matrix, thereby preventing or reducing external light reflection (or surface reflection).

According to various example embodiments of the present specification, the surface reflection of external light can be prevented or reduced, thereby providing low-reflection display device and achieving low power consumption.

According to various example embodiments of the present specification, by omitting the polarizing part, the display device can have improved flexibility and can be applied to foldable products in which the display area is folded.

However, effects obtainable from the present specification are not limited to the above effects, and other effects that are not described can be clearly understood by those skilled in the art to which the present specification pertains based on the above description.

Although various example embodiments of the present disclosure have been described with reference to the accompanying drawings, it will be understood by those skilled in the art that the above-described technical configurations of the present disclosure may be implemented in other specific forms without changing or departing from the technical spirit or essential features of the present disclosure. Accordingly, it should be understood that the above-described example embodiments are illustrative and not restrictive in all aspects. In addition, the protected scope of the present disclosure may be described by the claims to be described below and their equivalents, rather than the detailed description. In addition, the meaning and scope of the claims and all changed or modified forms derived from the equivalent concept should be construed as being included in the scope of the present disclosure.

What is claimed is:

1. A display device, comprising:
a substrate in which a plurality of sub-pixels each including a light-emitting area and a non-light-emitting area are defined;
a first insulating layer disposed on the substrate and having a first refractive index;
a second insulating layer disposed on the first insulating layer and having a second refractive index smaller than the first refractive index; and
a black matrix disposed on the second insulating layer in the non-light-emitting area,
wherein, in the light-emitting area, the second insulating layer has a recess in an upper surface of the second insulating layer.

2. The display device of claim 1, wherein, in the light-emitting area, an angle of a side surface of the second insulating layer is 20° or less.

3. The display device of claim 1, wherein a width of the recess increases upward.

4. The display device of claim 3, wherein a cross-sectional shape of the recess has a V shape, an inverted trapezoidal shape, or a U shape.

5. The display device of claim 1, further comprising a color filter on the black matrix and the second insulating layer,
wherein the color filter fills the recess.

6. The display device of claim 5, wherein the color filter is in direct contact with side surfaces and an upper surface of the second insulating layer.

7. The display device of claim 5, wherein a refractive index of the color filter is greater than the second refractive index of the second insulating layer.

8. The display device of claim 5, wherein, in the light-emitting area, the recess is provided as a plurality of recesses, and the plurality of recesses overlap a single color filter.

9. The display device of claim 5, wherein a thickness of a portion the color filter overlapping the recess is greater than a thickness of a portion of the color filter overlapping the second insulating layer.

10. The display device of claim 1, further comprising:
a thin-film transistor layer between the substrate and the first insulating layer;
a light-emitting part between the thin-film transistor layer and the first insulating layer; and
a touch part between the light-emitting part and the first insulating layer,
wherein the first insulating layer is in direct contact with the touch part.

11. The display device of claim 10, wherein:
the touch part includes a first touch conductive layer, a touch buffer layer on the first touch conductive layer, a second touch conductive layer on the touch buffer layer, and a touch insulating layer on the second touch conductive layer; and
the first insulating layer is in direct contact with the touch insulating layer.

12. The display device of claim 10, wherein:
the light-emitting part includes a first electrode, an organic layer on the first electrode, and a second electrode on the organic layer; and
the display device further comprises a bank which covers a periphery of the first electrode and has a black-based material.

13. The display device of claim 12, wherein a distance between a side surface of the bank and the light-emitting area is shorter than a distance between a side surface of the black matrix and the light-emitting area.

14. The display device of claim 1, wherein each of the first insulating layer and the second insulating layer includes an inorganic insulation material.
